(19) United States
(12) Patent Application Publication
(10) Pub. No.: US 2022/0359208 A1
(43) Pub. Date: Nov. 10, 2022

(54) PROCESS INTEGRATION TO REDUCE CONTACT RESISTANCE IN SEMICONDUCTOR DEVICE

(71) Applicant: Applied Materials, Inc., Santa Clara, CA (US)

(72) Inventors: Sankuei LIN, Los Gatos, CA (US); Pradeep SUBRAHMANYAN, Cupertino, CA (US)

(21) Appl. No.: 17/735,830

(22) Filed: May 3, 2022

Related U.S. Application Data
(60) Provisional application No. 63/324,615, filed on Mar. 28, 2022.
(60) Provisional application No. 63/185,766, filed on May 7, 2021.

(51) Int. Cl. H01L 21/285; H01L 27/092; H01L 29/06; H01L 29/423; H01L 29/45; H01L 29/786; H01L 21/02; H01L 21/8238; H01L 29/66

(52) U.S. Cl. CPC H01L 21/28518; H01L 27/092; H01L 29/0665; H01L 29/42392; H01L 29/45; H01L 29/78606; H01L 29/78696; H01L 21/0259; H01L 21/02532; H01L 21/823807; H01L 21/823814; H01L 29/66742

(57) ABSTRACT

Methods of forming a nanosheet field effect transistor (FET) device with reduced source/drain contact resistance are provided herein. In some embodiments, a method of forming an FET device includes: etching a nanosheet stack of the nanosheet FET device to form a plurality of first source/drain regions and a plurality of second source/drain regions, the nanosheet stack comprising alternating layers of nanosheet channel layers and sacrificial nanosheet layers; depositing a silicide layer in the plurality of first source/drain regions at ends of the nanosheet channel layers via a selective silicidation process to control a length of the nanosheet channel layers between the first source/drain regions; and performing a metal fill process to fill the plurality of first source/drain regions, wherein the metal fill extends from a lowermost nanosheet channel layer to above an uppermost nanosheet channel layer to facilitate the reduced source/drain contact resistance.

### CROSS-REFERENCE TO RELATED APPLICATIONS

This application claims benefit of U.S. provisional patent application Ser. No. 63/185,766, filed May 7, 2021, and provisional patent application Ser. No. 63/324,615, filed Mar. 28, 2022, both of which are herein incorporated by reference in their entireties.

### FIELD

Embodiments of the present disclosure generally relate to semiconductor devices, and more specifically, to nanosheet field-effect transistor device structures.

### BACKGROUND

Transistors are circuit components or elements that are often formed on semiconductor devices. Many transistors may be formed on a semiconductor device in addition to capacitors, inductors, resistors, diodes, conductive lines, or other elements, depending on the circuit design. Integrated circuits incorporate planar field-effect transistors (FETs) in which current flows through a semiconducting channel between a source and a drain, in response to a voltage applied to a control gate. As device dimensions have shrunk, new device geometries and structures and materials have experienced difficulty maintaining switching speeds without incurring failures.

Several new technologies emerged that have allowed chip designers to continue shrinking gate lengths. One particularly far-reaching technology change entailed re-designing the structure of the FET from a planar device to a three-dimensional device in which the semiconducting channel was replaced by a fin that extends out from the plane of the substrate. In such a device, commonly referred to as a FinFET, the control gate wraps around three sides of the fin so as to influence current flow from three surfaces instead of one. The improved control achieved with a 3-D design results in faster switching performance and reduced current leakage.

The FinFET concept was extended by development of a gate all-around FET (GAA FET), in which the gate fully wraps around the channel for maximum control of the current flow therein. In the GAA FET, the channel can take the form of a cylindrical nanowire that is isolated from the substrate. Existing GAA FETs are oriented horizontally, such that the nanowire extends in a direction that is parallel to the surface of the semiconductor substrate.

The FinFET concept was further extended by development of a nanosheet FET device, which is similar to the cylindrical nanowire concept except the device channel comprises one or more nanosheet layers in a stacked configuration where each nanosheet layer has a width that is substantially greater than a thickness of the nanosheet layer. A common gate structure is formed above and below each nanosheet layer and the increased width, as compared to a nanowire structure, facilitates an increase in drive current for a given footprint area. However, as 3-D devices continue to shrink in size, contact resistance of source/drain regions of nanosheet device structures may be too high due to limited contact surface area between source/drain regions and corresponding metal contacts.

Accordingly, the inventors have provided herein embodiments of nanosheet FET devices with reduced source/drain contact resistance and methods of forming such devices.

### SUMMARY

Methods of forming a nanosheet field effect transistor (FET) device with reduced source/drain contact resistance are provided herein. In some embodiments, a method of forming an FET device includes: etching a nanosheet stack of the nanosheet FET device to form a plurality of first source/drain regions and a plurality of second source/drain regions, the nanosheet stack comprising alternating layers of a plurality of nanosheet channel layers and a plurality of sacrificial nanosheet layers; depositing a silicide layer in the plurality of first source/drain regions at sidewalls of the plurality of nanosheet channel layers via a selective silicidation process to control a channel length of the plurality of nanosheet channel layers between adjacent first source/drain regions; and performing a metal fill process to fill the plurality of first source/drain regions, wherein the metal fill extends from a lowermost nanosheet channel layer of the plurality of nanosheet channel layers to above an uppermost nanosheet channel layer of the plurality of nanosheet channel layers to facilitate the reduced source/drain contact resistance.

In some embodiments, a method of forming a nanosheet field effect transistor (FET) device with reduced source/drain contact resistance, includes: forming a nanosheet stack on a substrate, the nanosheet stack comprising alternating layers of nanosheet channel layers and sacrificial nanosheet layers; etching the nanosheet stack of the nanosheet FET device to form a plurality of first source/drain regions and a plurality of second source/drain regions; applying a hard mask on the plurality of second source/drain regions; depositing a silicide layer in the plurality of first source/drain regions at sidewalls of the nanosheet channel layers via a selective silicidation process to control a channel length of the nanosheet channel layers between the first source/drain regions; performing a metal fill process to fill the plurality of first source/drain regions, wherein the metal fill extends from a lowermost nanosheet channel layer to above an uppermost nanosheet channel layer to facilitate the reduced source/drain contact resistance; applying a hard mask over the metal fill in the plurality of first source/drain regions; depositing a silicide layer in the plurality of second source/drain regions at sidewalls of the nanosheet channel layers exposed to the plurality of second source/drain regions via a selective silicidation process to control a length of the nanosheet channel layers between adjacent second source/drain regions; and performing a second metal fill process to fill the plurality of second source/drain regions, wherein the second metal fill extends from the lowermost nanosheet channel layer to above the uppermost nanosheet channel layer to facilitate the reduced source/drain contact resistance.

In some embodiments, a nanosheet field effect transistor (FET) device includes: a nanosheet stack comprising a plurality of nanosheet channel layers; and a source/drain region in contact with end portions of the plurality of nanosheet channel layers, wherein the source/drain region is filled with a metal fill extending below an uppermost one of the plurality of nanosheet channel layers and a silicide layer disposed between the metal fill and sidewalls of the plurality of nanosheet channel layers.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a flow chart of a method of forming a nanosheet field effect transistor (FET) device in accordance with at least some embodiments of the present disclosure.

FIG. 2 depicts a schematic isometric view of a nanosheet FET device having a plurality of source/drain regions.

FIG. 3 depicts a cross-sectional view of a portion of a nanosheet FET device in accordance with at least some embodiments of the present disclosure.

FIG. 4 depicts a cross-sectional view of a portion of a nanosheet FET device in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of nanosheet FET devices with reduced source/drain contact resistance and methods of forming such devices are provided herein. The methods provided herein increase a contact area between source/drain regions of the nanosheet FET devices and respective metal contacts to advantageously lower contact resistance therebetween, improving device performance. The methods provided herein also advantageously facilitate tuning a channel length via controlled deposition techniques for optimizing device performance.

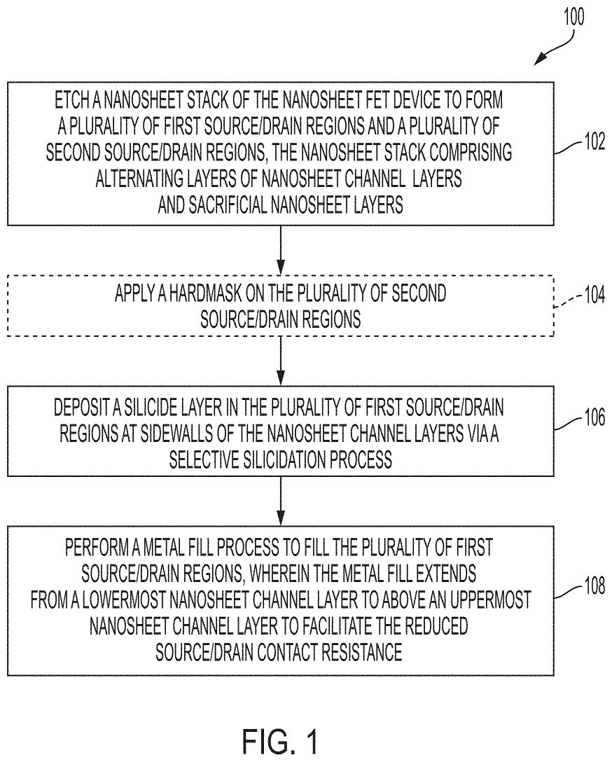

FIG. 1 depicts a flow chart of a method of forming a nanosheet field effect transistor (FET) device with reduced source/drain contact resistance in accordance with at least some embodiments of the present disclosure. At 102, the method 100 includes forming a nanosheet stack on a substrate (e.g., substrate 218), the nanosheet stack comprising alternating layers of nanosheet channel layers (e.g., plurality of nanosheet channel layers 206) and sacrificial nanosheet layers (e.g., plurality of sacrificial nanosheet layers 212). The nanosheet stack of the nanosheet FET device may be etched to form trenches (e.g., trenches 304) that define a plurality of first source/drain regions (e.g., plurality of first source/drain regions 202) and a plurality of second source/drain regions (e.g., plurality of second source/drain regions 204). The etch process may be an anisotropic dry etch process, a wet etch process, or any other suitable etch process. In some embodiments, the etch process vertically etches exposed portions of the nanosheet stack down to the substrate. In some embodiments, the etch process vertically etches exposed portions of the nanosheet stack and a portion of the substrate, or in other words, etches below an upper surface of the substrate.

At 104, the method 100 optionally includes applying a hard mask (e.g., hard mask 238) on the plurality of second source/drain regions. In some embodiments, the hard mask is deposited on the plurality of second source/drain regions prior to any deposition or fill processes conducted in the plurality of first source/drain regions, such as depositing a silicide layer in the plurality of first source/drain regions. In some embodiments, the method 100 includes forming inner spacers (e.g., inner spacers 226) in the plurality of first source/drain regions adjacent the plurality of nanosheet channel layers. In some embodiments, the spacers are formed of a dielectric material, for example, silicon nitride (SiN) or any suitable dielectric material.

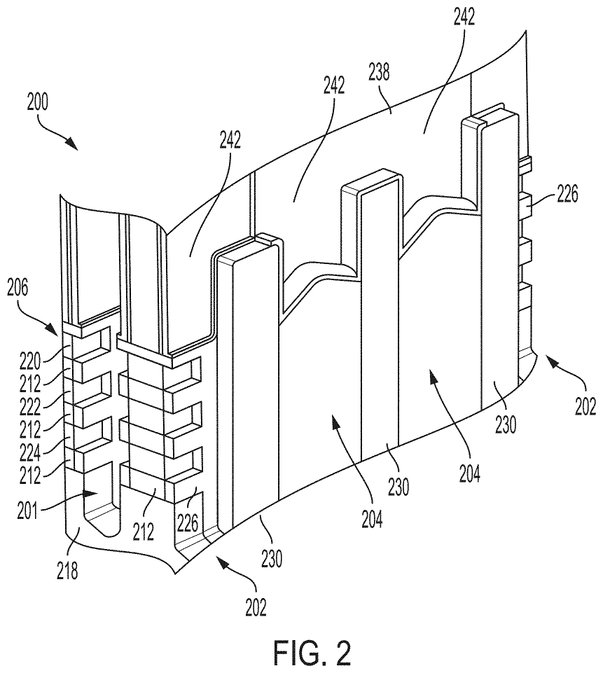

For example, FIG. 2 depicts a schematic isometric view of a nanosheet FET device, or device 200, having a plurality of source/drain regions in accordance with at least some embodiments of the present disclosure. In some embodiments, the plurality of source/drain regions 201 may generally include a plurality of first source/drain regions 202 and a plurality of second source/drain regions 204. In some embodiments, the plurality of first source/drain regions 202 correspond with an p-channel metal-oxide semiconductor (pMOS) areas of the device 200. In some embodiments, the plurality of second source/drain regions 204 correspond with n-channel metal-oxide semiconductor (nMOS) areas of the device 200. FIG. 1 depicts the plurality of second source/drain regions 204 filled with material and covered with a hard mask 238 and the plurality of first source/drain regions 202 at an unfilled intermediate step ready for subsequent deposition and fill processes. The plurality of first source/drain regions 202 and a plurality of second source/drain regions 204 may be separated via insulation layers 230 comprising, for example, low-K dielectric material such as silicon nitride (SiN), silicon oxynitride (SiON), silicon oxycarbonitride (SiOCN), or silicon oxycarbide (SiOC). Gate regions 242 may be disposed above the plurality of source/drain regions 201.

The device 200 generally comprises a plurality of nanosheet channel layers 206 alternating with a plurality of sacrificial nanosheet layers 212 deposited or disposed on a substrate 218 (e.g., in a stacked configuration, or stacked layers). In some embodiments, the plurality of nanosheet channel layers 206 have a thickness of about 5 to about 15 nanometers per layer. In some embodiments, the plurality of sacrificial nanosheet layers 212 have a thickness of about 5 to about 15 nanometers per layer. In some embodiments, the substrate 218 may be a semiconductor substrate that is formed of silicon (Si), silicon germanium (SiGe), or any other suitable semiconductor substrate material. In some embodiments, the plurality of nanosheet channel layers 206 include exactly three channel layers that are stacked, a first channel layer 220, a second channel layer 222, and a third channel layer 224, separated by layers of the plurality of sacrificial nanosheet layers 212. However, the device 200 may include more or less than three nanosheet channel layers. In some embodiments, the plurality of nanosheet channel layers 206 and the plurality of sacrificial nanosheet layers 212 are sequentially grown in an alternating manner via an epitaxial growth process.

In some embodiments, the plurality of nanosheet channel layers 206 consist essentially of silicon (Si), and the plurality of sacrificial nanosheet layers 212 consist essentially of silicon germanium (SiGe) with a desired Ge concentration. In some embodiments, the plurality of nanosheet channel layers 206 consist essentially of silicon germanium (SiGe) with a desired Ge concentration, and the plurality of sacrificial nanosheet layers 212 consist essentially of silicon (Si). In some embodiments, the desired Ge concentration is about 15 to about 40 percent by volume. In some embodiments, the plurality of nanosheet channel layers 206 and the plurality of sacrificial nanosheet layers 212 comprise single crystal semiconductor materials, such as single crystal silicon. In some embodiments, the plurality of sacrificial nanosheet layers 212 may be subsequently etched away selective to the material of the plurality of nanosheet channel layers 206 to release the plurality of nanosheet channel layers 206 for subsequent metal fill. The plurality of first source/drain regions 202 may include inner spacers 226 adjacent the plurality of sacrificial nanosheet layers 212

Referring back to FIG. 1, at 106, the method 100 includes depositing a silicide layer (e.g., silicide layer 322) in the plurality of first source/drain regions at ends of the nanosheet channel layers via a selective silicidation process to control a length of the nanosheet channel layers between the first source/drain regions. The silicide layer functions as a contact for the first source/drain regions as well as a material that lowers contact resistance. In some embodiments, the silicide layer includes at least one of titanium, nickel, palladium, ruthenium, molybdenum, platinum, osmium, or iridium. In some embodiments, the silicide layer comprises titanium silicide for nMOS areas and molybdenum or ruthenium for pMOS areas.

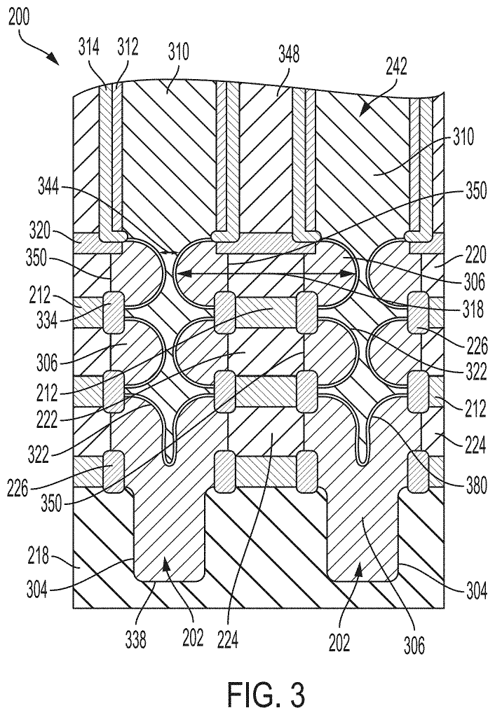

In some embodiments, prior to depositing the silicide layer in the plurality of first source/drain regions, as depicted in FIG. 3, the method 100 includes performing a controlled epitaxial growth process to deposit silicon or silicon germanium on exposed sidewalls (e.g., sidewalls 350) of the nanosheet channel layers and only partially fill the plurality of second source/drain regions prior to depositing the silicide layer in the plurality of second source/drain regions. In some embodiments, the controlled epitaxial growth process advantageously forms a gap (e.g., gap 344) between opposing sidewalls of the nanosheet channel layers to prevent epitaxial merge in the plurality of first source/drain regions. The silicide layer is deposited onto the epitaxially grown layer (e.g., epitaxial material 306). The channel lengths 318 of the device 200, which extend between adjacent metal fills (e.g., metal fill 310) may be advantageously controlled by controlling the thickness of epitaxial material deposited on the exposed nanosheet channel layers and controlling a thickness of the silicide layer.

FIG. 3 depicts a cross-sectional view of a portion of a nanosheet FET device 200 in accordance with at least some embodiments of the present disclosure. Each of the plurality of first source/drain regions 202 may be defined by a trench 304. In some embodiments, the inner spacers 226 may be formed in the trench 304 or adjacent the trench 304 via a process which laterally removes material from sidewalls of the plurality of sacrificial nanosheet layers 212 so that the sidewalls 334 of the plurality of sacrificial nanosheet layers 212 are recessed with respect to the sidewalls 350 of the plurality of nanosheet channel layers 206 adjacent the plurality of first source/drain regions 202. For example, the lateral etch may be performed using a wet etch process with an etch solution or a dry plasma etch that etches the plurality of sacrificial nanosheet layers 212 selective of the material of the plurality of nanosheet channel layers 206. An amount of lateral recess may be controlled through a timed etch. In some embodiments, dielectric material may be selectively deposited in the lateral recesses to form the inner spacers 226. In some embodiments, a conformal layer of dielectric material may be deposited in the plurality of first source/drain regions 202, including the recesses, followed with an etch back to remove excess material. In some embodiments, a width of the recess is substantially equal to a thickness of the inner spacers 226.

In some embodiments, the plurality of nanosheet channel layers 206 may be isolated from gate electrodes 348 disposed above the plurality of nanosheet channel layers 206 via respective upper spacers 320. In some embodiments, the upper spacers 320 are formed of the same material as the inner spacers 226. In some embodiments, a conformal layer of dielectric material may form both the inner spacers 226 and the upper spacers 320.

In some embodiments, epitaxial material 306 is grown from and extends from the sidewalls 350 of the plurality of nanosheet channel layers 206, for example, the first channel layer 220, the second channel layer 222, and the third channel layer 224. The epitaxial material 306 may also be grown from a lower surface 338 of the trench 304. In some embodiments, the epitaxial material 306 is grown from the lower surface 338 to a location vertically below an uppermost one of the plurality of nanosheet channel layers 206. In some embodiments, the epitaxial material 306 is grown from the lower surface 338 to a location vertically below a lowermost one of the plurality of nanosheet channel layers 206. In some embodiments, the epitaxial material 306 grown from the sidewalls 350 of the plurality of nanosheet channel layers 206 form bulbous shapes. In some embodiments, the epitaxial material 306 adjacent one of the plurality of nanosheet channel layers 206 does not merge with the epitaxial material 306 extending from any of the remaining channels of the plurality of nanosheet channel layers 206. In some embodiments, the epitaxial material 306 may comprise epitaxial silicon (Si) or silicon germanium (SiGe) doped with a suitable dopant for form nMOS or pMOS areas.

In some embodiments, a silicide layer 322 is disposed on the epitaxial material 306 and conforms with the epitaxial material 306. A metal fill 310 is disposed in the remainder of the trench 304 not occupied by one or more of the epitaxial material 306 and the silicide layer 322. A contact interface 380 between the metal fill 310 and the epitaxial material 306 or the silicide layer 322 is larger than conventional interfaces, advantageously resulting in lower contact resistance therebetween.

In some embodiments, gate spacers 312 may be disposed about the metal fill 310 in the gate regions 242. The gate spacers 312 may be made of a dielectric material. In some embodiments, second gate spacers 314 are disposed between the gate spacers 312 and the gate electrodes 348 to aid in modulating the conductance of the device 200. In some embodiments, the gate spacers 312 are made of a different material than the second gate spacers 314. In some embodiments, the gate spacers 312 are made of a low-K material and the second gate spacers 314 are made of a higher-K material. In some embodiments, the second gate spacers 314 may be consumed during processing, creating a larger volume for the gate electrodes 348.

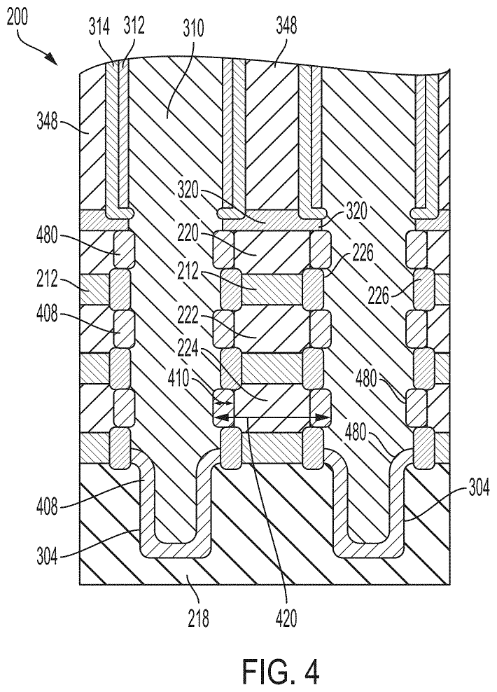

FIG. 4 depicts a cross-sectional view of a portion of a nanosheet FET device in accordance with at least some embodiments of the present disclosure. In some embodiments, a silicide layer 408 is deposited or formed in the trench 304 directly on the lower surface 338 thereof and on sidewalls 350 of the plurality of nanosheet channel layers 206 without the epitaxial material 306 discussed above with respect to FIG. 3. In some embodiments, the silicide layer 408 has a thickness 410 greater than a thickness of the silicide layer 322. In some embodiments, the thickness is about 1 to about 4 nanometers. In some embodiments, the thickness 410 optimizes device performance while minimizes short channel effects. The metal fill 310 is disposed in the remainder of the trench 304 not occupied by the silicide layer 408. In some embodiments, the metal fill 310 extends below the plurality of nanosheet channel layers 206. A channel length 420 may comprise a length of each respective layer of the plurality of nanosheet channel layers 206 plus the thickness 410 of the silicide layer 408 at both ends of each layer. The channel length 420 may be controlled by controlling the thickness 410 to tune the device 200 for optimal performance. In some embodiments, a channel length of the device 200 is about 10 to about 15 nanometers. A contact interface 480 between the metal fill 310 and the silicide layer 408 is larger than conventional interfaces, advantageously resulting in lower contact resistance therebetween. The device of FIG. 4 also advantageously does not require a source/drain implant and activation step, resulting in lower cost and lower thermal budget.

Returning back to FIG. 1, at 108, the method 100 includes performing a metal fill process to fill the plurality of first source/drain regions, wherein the metal fill (e.g., metal fill 310) extends from a lowermost nanosheet channel layer (e.g., third channel layer 224) to above an uppermost nanosheet channel layer (e.g., first channel layer 220) to facilitate the reduced source/drain contact resistance. The metal fill results in less epitaxial material (e.g., epitaxial material 306) disposed in the source/drain regions, which reduces epitaxial strain. However, the benefits of reduced source/drain contact resistance via the metal fill process described herein may offset the drawbacks of the reduced epitaxial strain. In some embodiments, the method 100 includes modulating the metal fill to enhance channel stress and compensate for any lost performance due to reduced epitaxial strain.

In some embodiments, the method 100 includes applying a hard mask over the metal fill in the plurality of first source/drain regions. In some embodiments, the method 100 includes performing similar process steps for the plurality of second source/drain regions after applying the hard mask over the metal fill in the plurality of first source/drain regions. For example, in some embodiments, the method includes performing a controlled epitaxial growth process to deposit silicon or silicon germanium on exposed sidewalls of the nanosheet channel layers in the plurality of second source/drain regions and only partially fill the plurality of second source/drain regions. In some embodiments, a silicide layer is deposited in the plurality of second source/drain regions followed by a metal fill. In some embodiments, the second metal fill extends from a lowermost nanosheet channel layer to above an uppermost nanosheet channel layer to facilitate the reduced source/drain contact resistance. In some embodiments, the inner spacers are formed in the plurality of second source/drain regions prior to depositing the silicide layer in the plurality of second source/drain regions. In some embodiments, after the method fill process, a suitable middle end of line (MEOL) or back end of line (BEOL) process may be performed on the device 200.

While the foregoing is directed to embodiments of the present disclosure, other and further embodiments of the disclosure may be devised without departing from the basic scope thereof. For ease of explanation, one or more layers, structures, and regions of a type commonly used to form semiconductor devices or structures may not be explicitly shown in the accompanying drawings. Any such layers, structures, and/or regions not explicitly shown may be present in the actual semiconductor device structures. Further, with respect to semiconductor processing techniques, the descriptions provided herein are not intended to encompass all of the processing procedures that may be required to form a functional semiconductor integrated circuit device.

1. A method of forming a nanosheet field effect transistor (FET) device with reduced source/drain contact resistance, comprising:
etching a nanosheet stack of the nanosheet FET device to form a plurality of first source/drain regions and a plurality of second source/drain regions, the nanosheet stack comprising alternating layers of a plurality of nanosheet channel layers and a plurality of sacrificial nanosheet layers;
depositing a silicide layer in the plurality of first source/drain regions at sidewalls of the plurality of nanosheet channel layers via a selective silicidation process to control a channel length of the plurality of nanosheet channel layers between adjacent first source/drain regions; and
performing a metal fill process to fill the plurality of first source/drain regions, wherein the metal fill extends from a lowermost nanosheet channel layer of the plurality of nanosheet channel layers to above an uppermost nanosheet channel layer of the plurality of nanosheet channel layers to facilitate the reduced source/drain contact resistance.

2. The method of claim 1, further comprising, prior to depositing the silicide layer, performing a controlled epitaxial growth process to deposit silicon or silicon germanium on exposed sidewalls of the plurality of nanosheet channel layers and only partially fill the plurality of first source/drain regions.

3. The method of claim 2, wherein the controlled epitaxial growth process prevents epitaxial merge in the plurality of first source/drain regions.

4. The method of claim 1, wherein the silicide layer is deposited or formed directly on a lower surface of the plurality of first source/drain regions and directly on the sidewalls of the plurality of nanosheet channel layers.

5. The method of claim 1, wherein the plurality of first source/drain regions correspond to pMOS areas of the nanosheet FET device and the plurality of second source/drain regions correspond to nMOS areas of the nanosheet FET device.

6. The method of claim 1, further comprising applying a hard mask on the plurality of second source/drain regions prior to depositing the silicide layer in the plurality of first source/drain regions.

7. The method of claim 1, wherein the silicide layer includes at least one of titanium, nickel, palladium, molybdenum, platinum, osmium, or iridium.

8. The method of claim 1, further comprising:
depositing a silicide layer in the plurality of second source/drain regions on sidewalls of the plurality of nanosheet channel layers disposed in the plurality of second source/drain regions via a selective silicidation process; and
performing a second metal fill process to fill the plurality of second source/drain regions, wherein the second metal fill extends from the lowermost nanosheet channel layer to above the uppermost nanosheet channel layer to facilitate the reduced source/drain contact resistance.

9. The method of claim 8, further comprising, prior to depositing the silicide layer in the plurality of second source/drain regions, performing a controlled epitaxial growth process to deposit silicon or silicon germanium on exposed sidewalls of the plurality of nanosheet channel layers disposed in the plurality of second source/drain regions and only partially fill the plurality of second source/drain regions.

10. A method of forming a nanosheet field effect transistor (FET) device with reduced source/drain contact resistance, comprising:
forming a nanosheet stack on a substrate, the nanosheet stack comprising alternating layers of nanosheet channel layers and sacrificial nanosheet layers;
etching the nanosheet stack of the nanosheet FET device to form a plurality of first source/drain regions and a plurality of second source/drain regions;
applying a hard mask on the plurality of second source/drain regions;
depositing a silicide layer in the plurality of first source/drain regions at sidewalls of the nanosheet channel layers via a selective silicidation process to control a channel length of the nanosheet channel layers between the first source/drain regions;
performing a metal fill process to fill the plurality of first source/drain regions, wherein the metal fill extends from a lowermost nanosheet channel layer to above an uppermost nanosheet channel layer to facilitate the reduced source/drain contact resistance;
applying a hard mask over the metal fill in the plurality of first source/drain regions;
depositing a silicide layer in the plurality of second source/drain regions at sidewalls of the nanosheet channel layers exposed to the plurality of second source/drain regions via a selective silicidation process to control a length of the nanosheet channel layers between adjacent second source/drain regions; and
performing a second metal fill process to fill the plurality of second source/drain regions, wherein the second metal fill extends from the lowermost nanosheet channel layer to above the uppermost nanosheet channel layer to facilitate the reduced source/drain contact resistance.

11. The method of claim 10, wherein the nanosheet channel layers are made of silicon and the sacrificial nanosheet layers are made of silicon germanium.

12. The method of claim 10, further comprising:
performing a controlled epitaxial growth process to deposit silicon or silicon germanium on exposed sidewalls of the nanosheet channel layers and only partially fill the plurality of first source/drain regions prior to depositing the silicide layer in the plurality of first source/drain regions; and
performing a controlled epitaxial growth process to deposit silicon or silicon germanium on exposed sidewalls of the nanosheet channel layers and only partially fill the plurality of second source/drain regions prior to depositing the silicide layer in the plurality of second source/drain regions.

13. The method of claim 10, further comprising:
forming a spacer between the sacrificial nanosheet layers and the plurality of first source/drain regions prior to depositing the silicide layer in the plurality of first source/drain regions; and
forming a spacer between the sacrificial nanosheet layers and the plurality of second source/drain regions prior to depositing the silicide layer in the plurality of second source/drain regions.

14. A nanosheet field effect transistor (FET) device, comprising:
a nanosheet stack comprising a plurality of nanosheet channel layers; and
a source/drain region in contact with end portions of the plurality of nanosheet channel layers, wherein the source/drain region is filled with a metal fill extending below an uppermost one of the plurality of nanosheet channel layers and a silicide layer disposed between the metal fill and sidewalls of the plurality of nanosheet channel layers.

15. The nanosheet FET device of claim 14, further comprising epitaxially grown silicon or silicon germanium disposed between the sidewalls of the plurality of nanosheet channel layers and the silicide layer.

16. The nanosheet FET device of claim 14, wherein the silicide layer is about 1 to about 4 nanometers thick.

17. The nanosheet FET device of claim 14, wherein the silicide layer includes at least one of titanium, nickel, palladium, molybdenum, platinum, osmium, or iridium.

18. The nanosheet FET device of claim 14, wherein a channel length of the nanosheet FET device is about 10 to about 15 nanometers.

19. The nanosheet FET device of claim 14, wherein the plurality of nanosheet channel layers are made of single crystal silicon.

20. The nanosheet FET device of claim 14, wherein the plurality of nanosheet channel layers comprise exactly 3 stacked layers.
